(19) United States
(12) Patent Application Publication
(10) Pub. No.: US 2007/0251444 A1
(43) Pub. Date: Nov. 1, 2007

(54) PEALD Deposition of a Silicon-Based Material

(75) Inventors: Michael Gros-Jean, Grenoble (FR); Daniel Benoit, Grenoble (FR); Jorge Luis Regolini, Bernin (FR)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(73) Assignee: STMicroelectronics S.A., Montrouge (FR)

(21) Appl. No.: 11/739,631

(22) Filed: Apr. 24, 2007

(30) Foreign Application Priority Data
Apr. 25, 2006 (FR) 0603684

(51) Int. Cl. C30B 23/00; C30B 28/14

(52) U.S. Cl. 117/92; 117/951; 117/952

(57) ABSTRACT

A process for depositing a silicon-based material on a substrate uses the technology of plasma-enhanced atomic layer deposition. The process is carried out over several cycles, wherein each cycle includes: exposing the substrate to a first precursor, which is an organometallic silicon precursor; and applying a plasma of at least a second precursor, different from the first precursor. Semiconductor products such as 3D capacitors, vertical transistor gate spacers, and conformal transistor stressors are made from the process.

### PRIORITY CLAIM

The present application is a translation of and claims priority from French Patent Application No. 06 03684 of the same title filed Apr. 25, 2006, the disclosure of which is hereby incorporated by reference.

### BACKGROUND OF THE INVENTION

1. Technical Field of the Invention

The present invention relates to deposition of silicon-based material on a substrate in a process for fabricating a semiconductor product.

The process is applicable in many fields. For example, the invention may be employed within the context of fabricating a three-dimensional capacitor or 3D capacitor.

2. Description of Related Art

The term “substrate” is understood to mean any material on which a silicon-based material is deposited. For example, in the case of a 3D capacitor, the substrate comprises a layer of a dielectric material into which a trench is cut, and also possibly other subjacent layers, for example electrodes.

The substrate may have a composition such that the maximum deposition temperature has to remain below a certain threshold. For example, the substrate may comprise copper or aluminum interconnects that run the risk of being damaged if the temperature exceeds 400° C. In another example, where the substrate may comprise doped zones—the temperature has to also remain below 400° C. so as to limit the diffusion of dopants. In other cases, a relatively low temperature allows to prevent a desorption of trapped contaminating species.

It is known to use a silane (SiH₄), ammonia (NH₃) and/or dinitrogen (N₂) plasma to deposit a silicon-based material on a substrate while still maintaining a relatively low temperature. The silane, ammonia and/or dinitrogen are introduced at specified flow rates and electrical power is applied so as to create a plasma. The composition of the layer formed is determined by the flow rates of the reactants and can thus be controlled relatively easily.

However, the substrate may have a relatively varied topology, that is to say the substrate has variations in relief on its surface, such as for example trenches or raised zones. Now, the use of a plasma for depositing a layer of silicon-based material on such a substrate makes it possible to obtain only a non-conformal layer of material.

The technology of plasma-enhanced atomic layer deposition (PEALD) allows relatively conformal layers of silicon-based material to be obtained, even for relatively non-planar substrates, not requiring relatively high temperatures. The principle of PEALD consists in exposing the substrate, in succession and alternately, to various precursors so that reactions between precursors take place on the surface of the substrate, these reactions being activated by means of a plasma.

The deposition typically takes place over several cycles, each cycle repeating the same steps.

For example, during one cycle, a tri chloro silane or TCS (SiCl₃H) precursor is introduced. TCS molecules are absorbed on the surface of the substrate, creating a chemical bond with the substrate. Following such a chemisorption, an ammonia plasma is applied. The chemisorbed TCS molecules then react with the ammonia molecules to form an atomic layer of silicon nitride (Si₃N₄). During the next cycle, the TCS is again introduced, etc.

Such a sequence of steps makes it possible to obtain a relatively conformal silicon nitride layer.

However, with the PEALD technology, the final composition of the layer formed is relatively difficult to control. There is a need in the art to remedy such a drawback.

### SUMMARY OF THE INVENTION

According to a first aspect, a process is presented for depositing a silicon-based material on a substrate by the technology of plasma-enhanced atomic layer deposition. The process is carried out over several cycles, each cycle comprising the steps consisting in exposing the substrate to a first precursor, which is an organometallic silicon precursor, and in applying a plasma of at least a second precursor, different from the first precursor.

The use of an organometallic silicon precursor allows the composition of the silicon-based material to be better controlled.

This is because it is relatively difficult for the TCS used as precursor in the prior art to react with ammonia, so that this reaction between the precursors constitutes a limiting step. The plasma is applied so as to facilitate this reaction, which remains relatively tricky to control. The composition of the material is therefore also relatively tricky to control.

The proposed process allows an organometallic silicon precursor having a relatively low activation energy to be chosen, so that the reaction between the precursors is relatively easy to obtain and to control.

Thus, the plasma application step may be carried out while controlling at least one parameter chosen from the partial pressure of the organometallic precursor, the partial pressure of the second precursor(s), the total pressure, the temperature, the power, and the dilution of the second precursor in an inert gas. This control allows the various characteristics of the deposited material to be better controlled, in particular the stoichiometry, the density, the density of certain bonds, especially N—H or Si—H bonds, the stress that the deposited material is liable to apply to the substrate, the electrical performance of the material, etc.

In addition, the deposition rate may thus be somewhat higher than in the prior art.

The use of an organometallic silicon precursor also prevents chlorinated residues being left in the silicon-based material, as may be the case when TCS is used as a silicon precursor.

The process may be used in many applications, for example for producing a 3D capacitor, a spacer for a transistor, or else a stressor.

A spacer allows the various doping zones of a CMOS transistor to be controlled. In addition, by controlling the properties of the layers of a spacer, it is also possible to control the stress applied by this spacer to a transistor channel, with a view to increasing the mobility in the channel.

A stressor applies a stress to the transistor. Specifically, it is possible to modify the mobility of the electrons or holes by compressing or expanding a crystal lattice. A stressor may therefore improve the mobility of a transistor channel.

In the case of a 3D capacitor, the substrate may comprise a layer of a dielectric material in which a trench is cut, and possibly other subjacent layers.

In the case of a spacer or a stressor, the substrate may comprise an n-type well, diffusion zones, a channel, a gate zone and possibly other subjacent layers.

There are a large number of organometallic silicon precursors so that for a given application, it is possible to choose a precursor having the suitable characteristics, especially activation energy and vapor pressure.

In particular, BTBAS (bis(tert-butylamino)silane) gives relatively satisfactory results hence, when a plasma is applied, the BTBAS may react with the second precursor(s) at relatively low temperatures, especially between 200° C. and 400° C.

Other organometallic precursors may be used, for example diethylsilane, alkoxy silanes, such as TEOS (tetraethoxysilane), aminosilanes, such as TDMAS (tri(dimethylamido)silane) or TRDMAS (tris(dimethylamide)silane), and alkoxy silanols, such as TPOSL (tri-t-pentoxysilanol).

The term “silicon-based material” is understood to mean a material comprising silicon in a non-negligible proportion, especially between 10 and 90% by number of atoms. The term “silicon-based material” therefore covers a wide range of materials, comprising especially dielectric materials. This range includes silicon nitride (Si₃N₄), silicon oxide (SiO₂), silicon oxynitride (of the SiₓO_{y}N_{z} type), silicon carbonitrides (of the SiₓC_{y}N_{z} type), materials comprising molecules of the SiOC, SiₓN_{y}H_{z} type, and also mixtures thereof This range of materials also includes materials based on amorphous or polymorphic silicon.

The silicon-based material thus formed depends on the second precursor(s) used. The use of a nitrogen precursor, for example ammonia, as second precursor may lead to materials of the Si₃N₄, SiCN, SiₓN_{y}H_{z}, SiₓO_{y}N_{z} or SiₓO_{y}N_{z}H_{w} type. The use of an oxygen precursor, for example (O₂) or a nitrogen oxide (NO or NO₂), may lead to materials of the SiO₂, SiₓO_{y}N_{z}, SiₓO_{y}C_{z} or SiₓO_{y}N_{z}H_{w} type.

The cycles of the process according to one aspect may also comprise at least one purge step. For example, a purge may be carried out between the step of exposure to the organometallic precursor and the step of applying the plasma so as to substantially empty the chamber of the organometallic silicon precursor. Thus, reactions between the organometallic precursor and the second precursor(s) other than on the surface of the substrate are avoided, which reactions could result in the formation of undesirable particles.

A purge may also be carried out at the end of a cycle, before the organometallic precursor is introduced into the chamber for the next cycle, so as to ensure that no plasma remains in the chamber. This purge may for example last a few tenths of a second, or even a few seconds.

Alternatively, no purge step is carried out so as to allow relatively rapid deposition.

Alternatively, a partial purge is carried out. For example, the organometallic precursor is roughly removed, typically so that the partial pressure of the remaining organometallic precursor is below a threshold above which the organometallic precursor undergoes a volume reaction with the second precursor(s) when a given plasma is applied. This threshold therefore depends largely on the deposition conditions. The term “volume reaction” is understood to mean a reaction other than on the surface of the substrate, that is to say a reaction with the non-chemisorbed molecules.

According to another example, it is the second precursor in plasma form that is roughly removed, so as to avoid volume reactions with the organometallic precursor.

A partial purge prevents the formation of undesirable particles, while avoiding a considerable slow-down of the process.

In a second aspect, a semiconductor product is presented that includes a 3D capacitor comprising a layer made of a silicon-based material, the material of said layer also comprising carbon residues.

The term “carbon residues” is understood to mean residues in proportions of carbon atoms ranging between a few ppm (parts per million) and a few percent, for example a proportion of carbon atoms of around 0.1%. These carbon residues derive in fact from the use of an organometallic silicon precursor in a PEALD process according to the first aspect. The layer made of a silicon-based material is therefore relatively conformal and of relatively controlled composition. Furthermore, the maximum deposition temperature may remain relatively low, so that sensitive parts of the semiconductor product, for example copper interconnects, are not damaged owing to the deposition.

According to a third aspect, a semiconductor product comprises a spacer comprising a layer made of a silicon-based material, the material of said layer also comprising carbon residues.

According to a fourth aspect, a semiconductor product comprises a stressor comprising a layer made of a silicon-based material, the material of said layer also comprising carbon residues.

In an embodiment, a method of forming a semiconductor product comprises: performing plasma-enhanced atomic layer deposition to deposit a silicon-based material on a substrate. Performing is accomplished over a plurality of cycles depositing plural layers, wherein each cycle comprises: exposing the substrate to an organometallic precursor; and applying a plasma to cause deposition of the silicon-based material layer.

### BRIEF DESCRIPTION OF THE DRAWINGS

Other features and advantages of the invention will become apparent upon reading the description that follows. This is purely illustrative and should be read with regard to the appended drawings in which:

FIG. 1 is a timing diagram illustrating one example of the PEALD process according to one embodiment of the invention;

FIG. 2 is a timing diagram illustrating another example of the PEALD process according to one embodiment of the invention; and

FIGS. 3, 4 and 5 show examples of semiconductor products according to embodiments of the invention.

### DETAILED DESCRIPTION OF THE DRAWINGS

In the figures, identical references are used to denote analogous or similar objects.

Examples of the PEALD Process

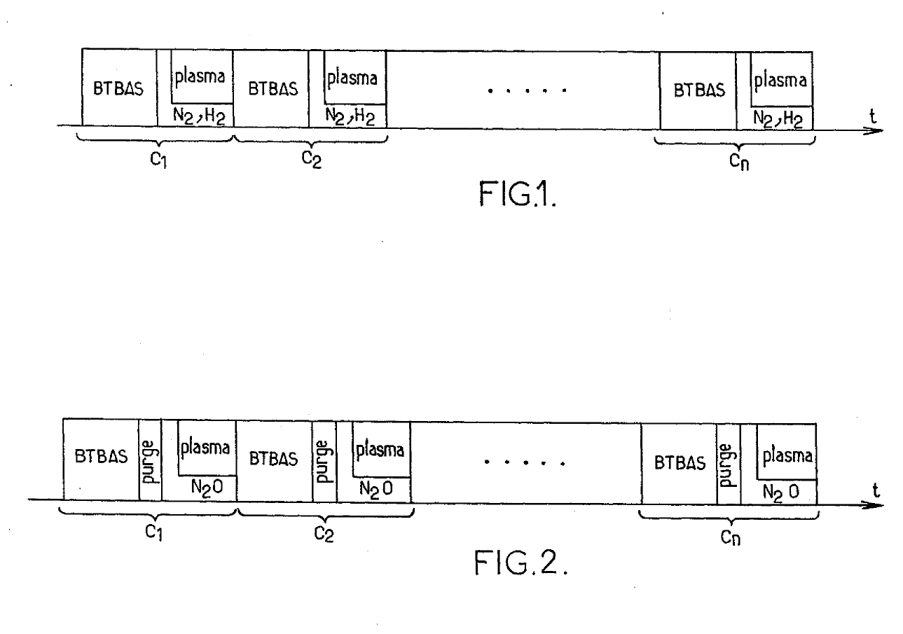

FIGS. 1 and 2 illustrate two examples of the PEALD process used to deposit a silicon-based material on a substrate. The deposition takes place over several cycles C₁, C₂, . . . , Cₙ, each cycle comprising the steps of:
exposing the substrate to BTBAS; and
applying a plasma of at least one other precursor.

In both these examples, the pressure in the chamber during application of the plasma may for example be between 1 Pa and 10⁴ Pa. The temperature in the chamber may be such that the temperature of the substrate is between 100° C. and 600° C. The total flow rate into the chamber may be between about 10⁻⁶ mol/s and 0.2 mol/s. Radio frequency power is applied, this power possibly being between 1 W and 10 kW.

According to the first example, illustrated by FIG. 1, the silicon-based material comprises the material of the SiₓN_{y}H_{z} type, and a plasma of a dinitrogen (N₂)/dihydrogen (H₂) mixture is applied. The dinitrogen and the dihydrogen are diluted in an inert gas, for example helium or argon. The partial pressures of these precursors may for example be between about 10⁻² Pa and 10⁴ Pa.

The stoichiometry of the SiₓN_{y}H_{z} type product obtained depends on several parameters, in particular the electric power applied to the electrodes, the total pressure, the flow rates of the various gases, and the partial pressures of the BTBAS, N₂ and H₂ reactants. The partial pressures of the reactants may be controlled by varying the flow rates of the reactants and the total flow rate into the chamber.

Alternatively, an ammonia plasma may be applied, the ammonia partial pressure also possibly being between about 10⁻² Pa and 10⁻⁴ Pa.

According to the second example, illustrated by FIG. 2, the silicon-based material comprises a silicon oxynitride (of the SiₓO_{y}N_{z} type) and a nitrous oxide (N₂O) plasma is applied. The partial pressure of this precursor may for example be between about 10⁻² Pa and 10⁴ Pa.

In this second example, each cycle C₁, C₂, . . . , Cₙ also comprises a purge step before the plasma application step. This purge step allows to empty the chamber of the non-chemisorbed BTBAS and thus prevent volume reaction between the BTBAS and the nitrous oxide.

In both these examples, the BTBAS may have a partial pressure of between about 10⁻² Pa and 10⁴. To avoid any risk of condensation, the BTBAS partial pressure is controlled so as to remain below the BTBAS vapor pressure for the coldest point in the chamber.

Examples of Applications for Obtaining Semiconductor Products

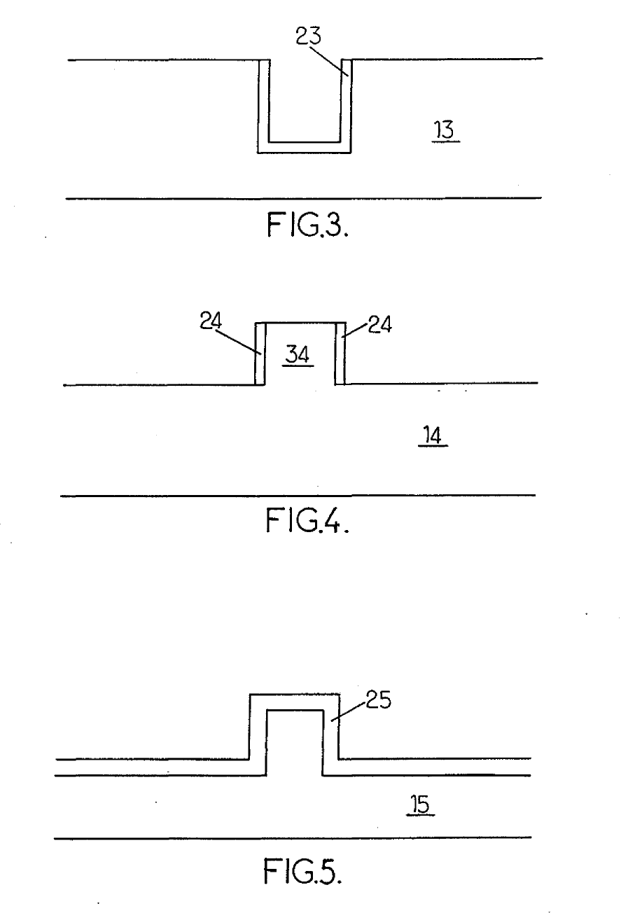

FIGS. 3, 4 and 5 show examples of semiconductor products according to embodiments of the invention.

FIG. 3 shows very schematically a 3D capacitor comprising a layer 23 made of a silicon-based material deposited on a substrate 13.

The substrate 13 comprises a layer of a dielectric material into which a trench is cut. The substrate 13 may possibly comprise other layers (not shown), for example electrodes of the capacitor 3D, and also copper interconnects (not shown), etc.

The trench may be obtained by an anisotropic etching step. After the layer made of silicon-based material has been deposited using a PEALD process according to one aspect of the invention, a polishing step of the CMP (chemical-mechanical polishing) type makes it possible to remove the layer deposited on the surface of the layer of dielectric material, so that only the internal walls of the trench are coated with the layer of silicon-based material. This layer forms a relatively conformal coating on the internal walls of the trench.

FIG. 4 shows very schematically a transistor that comprises a spacer 24 on the vertical walls of a raised gate zone 34. The spacer comprises a layer 24 of a silicon-based material deposited conformally on a substrate 14.

The substrate 14 may comprise diffusions zones (not shown), a channel (not shown), etc.

After the layer of silicon-based material has been deposited using a PEALD process according to one aspect of the invention, an anisotropic etching step is carried out so as to remove the layer on the substantially horizontal surfaces, such as the plane of the substrate 14. The layer 24 thus obtained is thus present only along the substantially vertical walls of the gate zone 34.

FIG. 5 shows very schematically a transistor that comprises a stressor 25. The stressor comprises a layer 25 of a silicon-based material deposited conformally on a substrate 15 using a process described herein.

The substrate 15 may comprise diffusion zones (not shown), a channel (not shown), etc.

Because the layer 25 is a conformal layer, it applies a substantially uniform stress.

These three semiconductor products may be obtained using a PEALD process according to one embodiment, this process having the advantages of not requiring excessively high temperatures, of allowing relatively conformal layers to be deposited and of forming layers of relatively controlled composition. The layers 23, 24, 25 are obtained using an organometallic precursor, which means that the materials of these layers include organic residues (such as carbon residues).

These organic residues may be detected by analyzing the layer of silicon-based material, for example using a SIMS (secondary ion mass spectroscopy) method.

In the above description, when a first element, such as for example a layer or a zone, was described as being “on” a second element, it should of course be understood that the first element may be directly on the second element or that intermediate elements may be located between the first element and the second element.

Although preferred embodiments of the method and apparatus have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A process for depositing on a substrate by the technology of plasma-enhanced atomic layer deposition a silicon-based material selected from the group consisting of materials based on amorphous or polymorphic silicon, silicon nitride, silicon oxide, silicon oxynitride of the SiₓO_{y}N_{z} type, silicon carbonitrides of the SiₓC_{y}N_{z} type, materials of the SiₓO_{y}C_{z} type, materials of the SiₓO_{y}N_{z}H_{w} type, materials of the SiₓN_{y}H_{z} type and mixtures thereof, the process being carried out over several cycles, each cycle comprising:
exposing the substrate to a first precursor, which is an organometallic silicon precursor; and
applying a plasma of at least a second precursor, different from the first precursor.

2. The deposition process according to claim 1, wherein the second precursor comprises a nitrogen precursor.

3. The deposition process according to claim 1, wherein the second precursor comprises an oxygen precursor.

4. The deposition process according claim 1, wherein each cycle further comprises a purging between exposing the first precursor and applying the plasma.

5. The deposition process according to claim 1, wherein each cycle further comprises a purging at the end of the cycle.

6. The deposition process according to claim 1, wherein the organometallic silicon precursor comprises BTBAS.

7. A semiconductor product comprising a 3D capacitor which comprises a layer made of a silicon-based material, the material of said layer also comprising carbon residues.

8. A semiconductor product comprising a spacer which comprises a layer made of a silicon-based material, the material of said layer also comprising carbon residues.

9. A semiconductor product that comprises a stressor which comprises a layer made of a silicon-based material, the material of said layer also comprising carbon residues.

10. A method of forming a semiconductor product, comprising:
performing plasma-enhanced atomic layer deposition to deposit a silicon-based material on a substrate, said silicon-based material being selected from the group consisting of materials based on amorphous or polymorphic silicon, silicon nitride, silicon oxide, silicon oxynitride of the SiₓO_{y}N_{z} type, silicon carbonitrides of the SiₓC_{y}N_{z} type, materials of the SiₓO_{y}C_{z} type, materials of the SiₓO_{y}N_{z}H_{w} type, materials of the SiₓN_{y}H_{z} type and mixtures thereof;
wherein performing is accomplished over a plurality of cycles depositing plural layers; and
wherein each cycle comprises:
exposing the substrate to an organometallic precursor; and
applying a plasma to cause deposition of the silicon-based material layer.

11. The method of claim 10 wherein the deposited silicon-based material layer comprises an electrode of a 3D capacitor.

12. The method of claim 11 further comprising forming a trench in the substrate prior to performing plasma-enhanced atomic layer deposition and polishing a top of the substrate after completion of the cycles to leave the deposited silicon-based material layer only within the trench.

13. The method of claim 10 wherein the deposited silicon-based material layer comprises a spacer for a transistor.

14. The method of claim 13 further comprising forming a raised gate structure above the substrate prior to performing plasma-enhanced atomic layer deposition and etching after completion of the cycles to remove the deposited silicon-based material layer from horizontal surfaces.

15. The method of claim 10 wherein the deposited silicon-based material layer comprises a stressor for a transistor.

16. The method of claim 15 further comprising forming a raised gate structure above the substrate prior to performing plasma-enhanced atomic layer deposition, the silicon-based material layer being conformally to apply substantially uniform stress to the raised gate structure.

17. The method of claim 10 wherein the deposited silicon-based material layer includes organic residues.

18. The method of claim 10 further including purging between exposing and applying.

19. The method of claim 10 further including purging after completion of a cycle.

20. The method of claim 10 wherein the organometallic precursor is BTBAS.
